(19) United States
(12) Patent Application Publication
(10) Pub. No.: US 2026/0343878 A1
(43) Pub. Date: Oct. 29, 2026

(54) METHOD OF MANUFACTURING A MEMORY DEVICE

(71) Applicant: United Semiconductor (Xiamen) Co., Ltd., Xiamen (CN)

(72) Inventor: Xiao Jun Li, Xiamen (CN)

(73) Assignee: United Semiconductor (Xiamen) Co., Ltd., Xiamen (CN)

(21) Appl. No.: 19/211,314

(22) Filed: May 19, 2025

(30) Foreign Application Priority Data
Apr. 27, 2025 (CN) 202510538043.3

(51) Int. Cl. H10B 41/30; H10D 30/01; H10D 30/68

(52) U.S. Cl. CPC H10B 41/30; H10D 30/0411; H10D 30/683; H10D 30/6892

(57) ABSTRACT

A method for manufacturing a memory device, which includes forming two stacked structures on a substrate, where the stacked structure includes a floating gate, a control gate, and a hard mask. A polysilicon layer is formed between the two stacked structures and on outer sides of the two stacked structures. A photolithography process is performed to pattern the hard masks and the polysilicon layer, such that a contact opening is formed in each of the hard masks to expose the control gate. The polysilicon layer on the outer side of the two stacked structures is then converted into two word lines.

### BACKGROUND OF THE INVENTION

### 1. Field of the Invention

The present invention pertains to the field of semiconductor technology, and more specifically, to a method for manufacturing a memory device that integrates the hard mask opening and word line patterning steps. It is particularly well-suited for applications involving high-performance, low-power, and low-leakage logic devices utilizing polysilicon gate/high-k metal gate (HKMG) architectures. Additionally, it is applicable to a wide range of related products and manufacturing processes, including mixed-signal devices, embedded memory, BCD (Bipolar-CMOS-DMOS) technologies, and high-voltage devices.

### 2. Description of the Prior Art

Split-gate non-volatile flash memory cells-comprising a select gate, a floating gate, a control gate, and an erase gate are well-established in the field. It is also a common practice to integrate logic devices (i.e., low-voltage and/or high-voltage logic devices) on the same silicon chip. In such integrated processes, certain process steps can be shared between the memory and logic devices. For instance, a single polysilicon deposition step may be employed to simultaneously form gate structures for both device types. This integration yields what is known as embedded memory, which offers key advantages such as high integration density, reduced chip area, lower manufacturing cost, and enhanced overall performance.

Nevertheless, some of the additional process steps required for embedded memory fabrication may negatively impact the performance or reliability of the logic devices, and vice versa. Consequently, integrating both memory and logic devices on a single wafer presents significant technical challenges and process complexity. To address these issues, those skilled in the art continually seek to streamline the process steps for embedded memory—aiming to reduce cost, shorten process cycle times, and ultimately improve the competitiveness of the final product.

### SUMMARY OF THE INVENTION

In light of the challenges associated with conventional techniques, the present invention introduces a novel method for manufacturing a memory device. A key feature of this method is the integration of the hard mask contact opening and word line patterning of the memory cell into a single process step, thereby reducing the need for additional photomasks and photolithography steps.

The objective of the present invention is to provide a method of manufacturing a memory device, including: providing a substrate; sequentially forming a first insulating layer, a first silicon layer, a second insulating layer, a second silicon layer, and a mask layer over the substrate; patterning the mask layer, the second silicon layer, and the second insulating layer into two stacked structures, wherein the mask layer, the second silicon layer, and the second insulating layer are respectively transformed into a hard mask, a control gate, and a blocking oxide layer within each of the two stacked structures; patterning the first silicon layer and the first insulating layer into a floating gate and a tunnel oxide layer within each of the two stacked structures; forming a source in the substrate between the two stacked structures; forming a polysilicon layer between and outside the two stacked structures; performing a photolithography process to pattern the two hard masks and the polysilicon layer, thereby forming a contact opening in each hard mask to expose the control gates, and transforming the polysilicon layer outside the two stacked structures into two word lines; forming a drain on each outer side of the two word lines; and forming contacts in the two contact openings to electrically connect to the two control gates.

Specifically, the present invention is well-suited for applications involving high-performance, low-power, and low-leakage logic devices utilizing polysilicon gate/high-k metal gate (HKMG) architectures. Additionally, it is applicable to a wide range of related products and manufacturing processes, including mixed-signal devices, embedded memory, BCD (Bipolar-CMOS-DMOS) technologies, and high-voltage devices.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8, FIG. 9, FIG. 10, FIG. 11, FIG. 12, and FIG. 13 are schematic cross-sectional views illustrating the manufacturing process of a memory device in accordance with an embodiment of the present invention.

It should be noted that all the figures are diagrammatic and illustrative. Relative dimensions and proportions of parts in the drawings have been shown exaggerated or reduced in size for the sake of clarity and convenience. The same reference signs and numerals are generally used to refer to corresponding or similar features in various modified or alternative embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

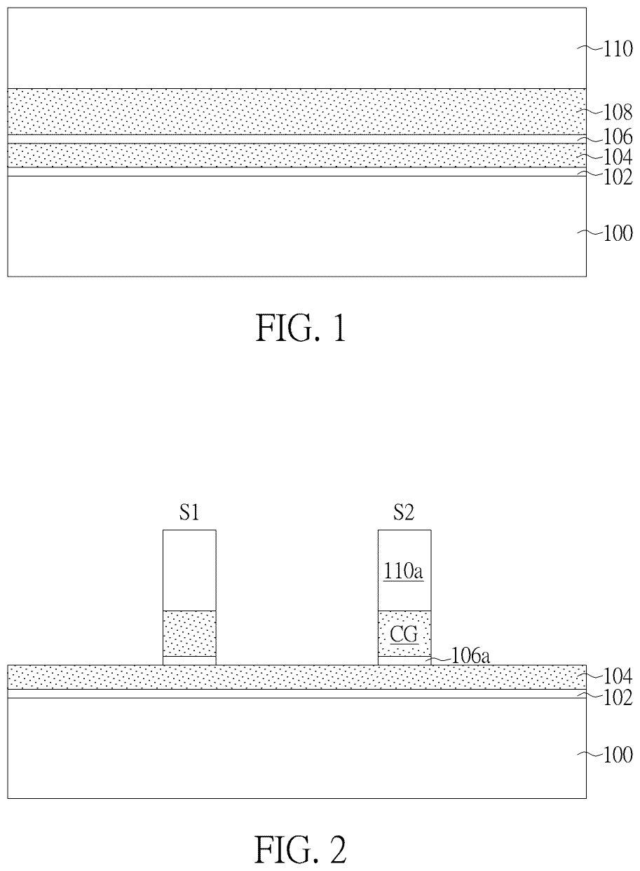

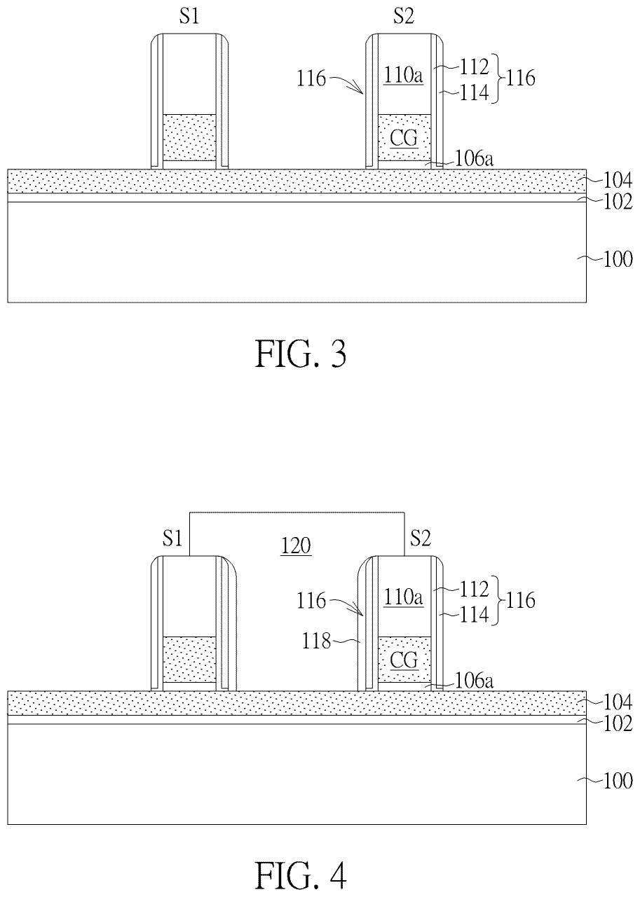

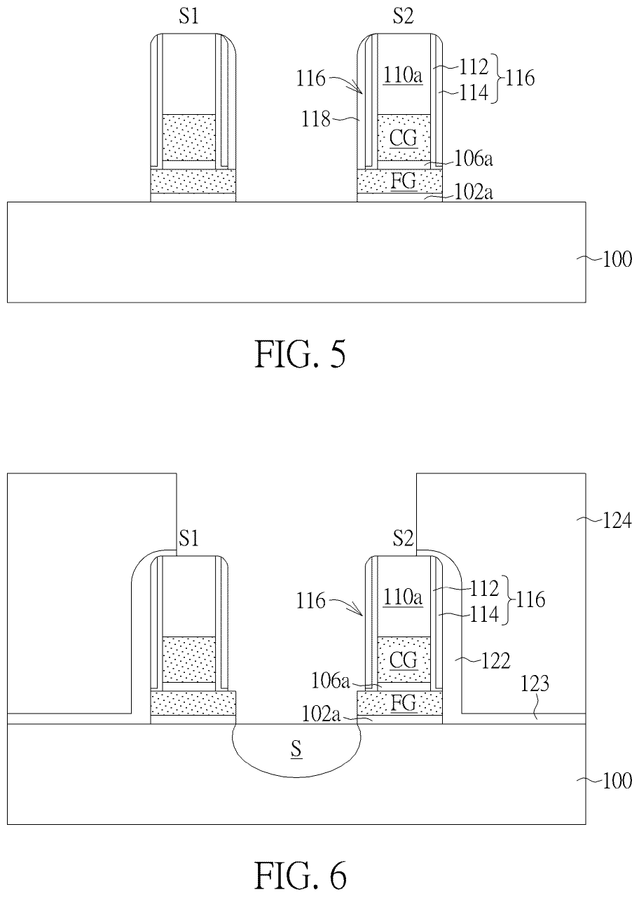

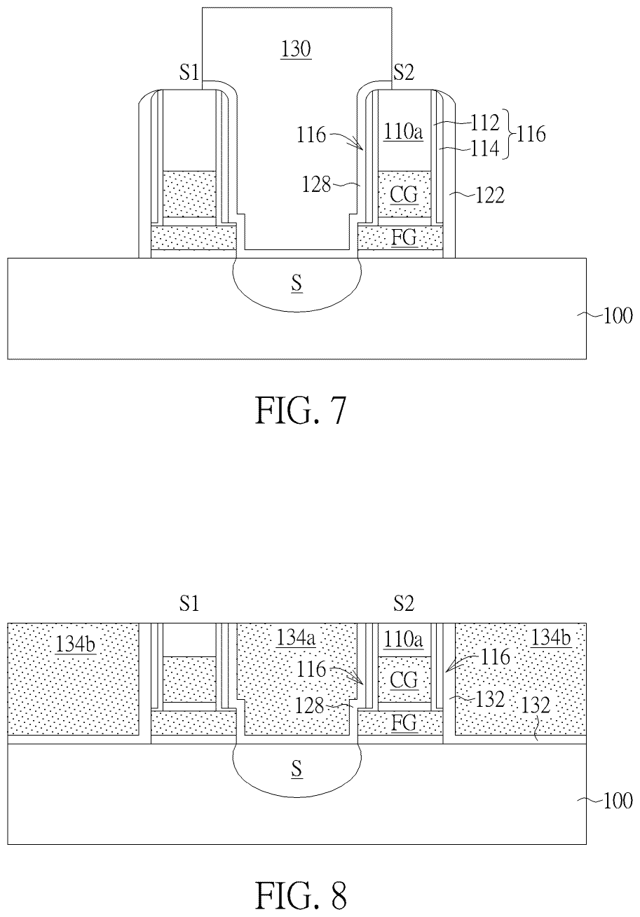

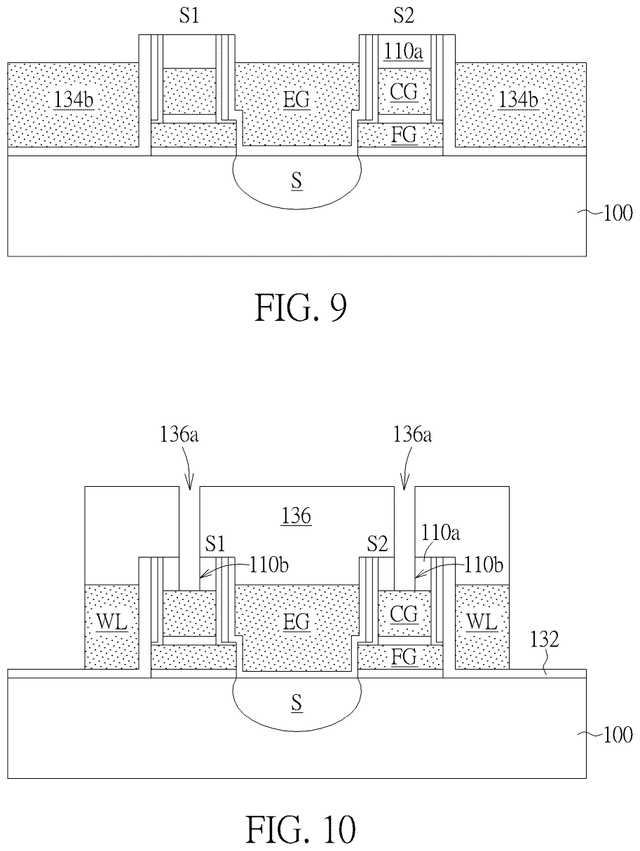

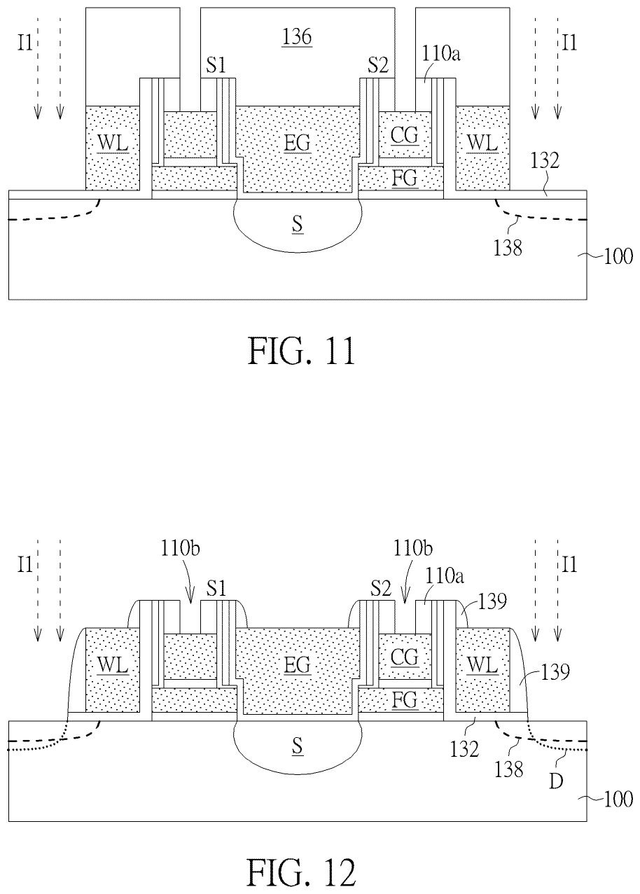

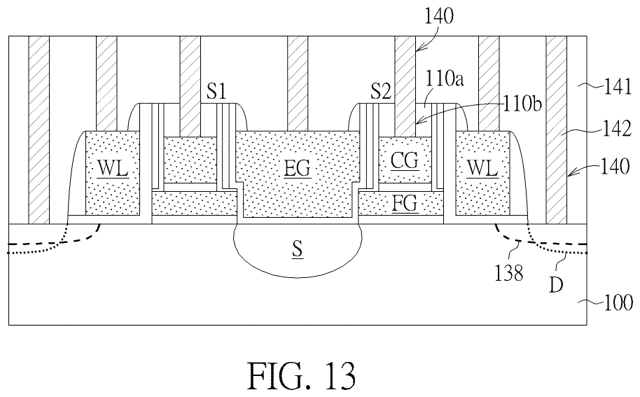

The following section provides a detailed description of an embodiment of the method of the present invention, with reference to FIGS. 1 through 12 in sequential order. These schematic cross-sectional views illustrate the step-by-step manufacturing process for forming paired memory cells within a designated memory cell region on a substrate. As used herein, the term “paired memory cells” refers, for example, to memory cells based on the ESF3 (3rd-Generation Embedded SuperFlash) architecture, in which two memory cells share a common source electrode that serves as a source line, along with a shared erase gate. The memory structure further includes additional components such as a word line (serving as the select gate), a control gate, a floating gate, and a bit line. It should be emphasized that, while the embodiment illustrated herein adopts the ESF3 memory architecture, the invention is not limited to this specific type. Rather, it is equally applicable to other memory architectures that embody the same inventive principles and exhibit similar structural features. Unless otherwise stated, the various material layers described throughout the text and depicted in the figures may be formed using any suitable deposition technique, including but not limited to chemical vapor deposition (CVD), physical vapor deposition (PVD), and atomic layer deposition (ALD).

Please refer first to FIG. 1. In the initial step, a first insulating layer 102—such as a silicon oxide layer—is formed on a substrate 100, which may be, for example, a P-type monocrystalline silicon substrate. This insulating layer serves as a tunnel oxide between the substrate 100 and the floating gate to formed in later steps. Subsequently, a first silicon layer 104 is deposited over the first insulating layer 102. This silicon layer may consist of either monocrystalline or amorphous silicon. It is then patterned through a photolithography process into elongated active regions (not shown), which will later be segmented into discrete floating gates during subsequent process steps. Following this, a second insulating layer 106 is formed over the first silicon layer 104. This layer may be composed of silicon oxide or an ONO (Oxide-Nitride-Oxide) composite stack, and functions as the blocking oxide between the floating gate and the control gate in the memory device. Next, a second silicon layer 108 is formed over the second insulating layer 106. This layer, composed of either monocrystalline or amorphous silicon, is i designated as the material layer for the control gate to be defined in subsequent steps. Finally, a mask layer 110 is formed over the second silicon layer 108. This layer may consist of silicon nitride, an ONO composite stack, or a NON (Nitride-Oxide-Nitride) composite stack, and serves as a hard mask for use in the subsequent etching process.

Please refer to FIG. 2. Following the formation of the aforementioned layer stack, a photolithography process is carried out to pattern the mask layer 110, the second silicon layer 108, and the second insulating layer 106 in the aforementioned layer structure. This patterning step results in the formation of paired stacked structures, designated as S1 and S2, as illustrated in the figure. Specifically, a photoresist featuring the desired stacked pattern is used as a mask during an anisotropic etching process to remove the unmasked portions of the mask layer 110, second silicon layer 108, and second insulating layer 106, thereby exposing the underlying first silicon layer 104. In this step, the patterned second silicon layer 108 functions as the control gate CG of the memory cell, the second insulating layer 106 becomes the blocking oxide layer 106a between the control gate CG and the floating gate to be formed later; and the mask layer 110 is transformed into the hard mask 110a of the memory cell. In this embodiment, the region between the two stacked structures S1 and S2 is referred to as the inner region, while the regions outside of the two stacked structures S1 and S2 are referred to as outer regions.

Please refer to FIG. 3. After the control gates (CG) have been formed within the stacked structures S1 and S2, a first spacer layer 112 and a second spacer layer 114 are sequentially deposited over the entire surface, covering the stacked structures. The first and second spacer layers may be composed of silicon oxide and silicon nitride, respectively, though alternative materials may also be utilized depending on specific design or process requirements. An anisotropic etching process is then applied to the first and second spacer layers 112 and 114 to form composite spacers 116 along the sidewalls of the stacked structures S1 and S2. The composite spacer 116 consists of the first spacer layer 112 on the inner side and the second spacer layer 114 on the outer side. In this embodiment, the spacers 116 serve to protect the already-formed hard mask 110a and control gate CG, and are also used to define the pattern for the floating gates to be formed in subsequent process steps.

Please refer to FIG. 4. Following the formation of the spacers 116, a third spacer layer 118 is formed over the existing spacers 116. This layer, typically composed of silicon oxide, may be formed using a process similar to that employed for the previous spacers 116—namely, by first depositing a conformal material layer over the surface of the stacked structures S1 and S2, followed by an anisotropic etching process to shape it into spacers. Once the third spacer layer 118 is formed, a photoresist 120 is applied over the inner region between the stacked structures S1 and S2. In this embodiment, the photoresist 120 fully covers the inner region and partially extends onto the adjacent stacked structures S1 and S2, while leaving the spacer on outer regions exposed. Using the photoresist 120 as a mask, an isotropic etching process is then performed to remove the exposed portions of the third spacer layer 118 in the outer regions. As a result, the spacers 116 in the outer regions consist of only the first spacer layer 112 and the second spacer layer 114, whereas the spacers 116 in the inner region retain all three layers: the first spacer layer 112, the second spacer layer 114, and the third spacer layer 118. This deliberate variation in spacer thickness between the inner and outer regions can be used in subsequent process steps to define the desired floating gate pattern.

Please refer to FIG. 5. After the third spacer layer 118 in the outer regions is removed, the photoresist 120 is stripped away. Then, using the stacked structures S1 and S2 along with their inner and outer spacers 116 as a mask, an anisotropic etching process is performed to pattern the first silicon layer 104 and the first insulating layer 102. As a result of this etching step, the first silicon layer 104 is transformed into the floating gate FG of the memory cell, while the first insulating layer 102 becomes the tunnel oxide layer 102a between the floating gate FG and the substrate 100. This process completes the full structural definition of the memory cell's stacked structures S1 and S2, which now—from top to bottom—include the hard mask 110a, control gate CG, blocking oxide layer 106a, floating gate FG, and tunnel oxide 102a. It is worth noting that, due to the presence of the third spacer layer 118, the floating gate FG in this embodiment extends horizontally beyond the control gate CG positioned above it. This structural arrangement enhances electric field control, increases storage density, and improves both programming and erase efficiency. In some implementations, a portion of the thinner first insulating layer 102 may be intentionally retained on the substrate 100 to help prevent substrate damage.

Please refer to FIG. 6. Following the formation of the floating gates FG and tunnel oxide layer 102a, a silicon oxide layer is formed over the stacked structures S1 and S2. An anisotropic etching process is then performed, resulting in the formation of silicon oxide spacers 122 along the sidewalls of the stacked structures S1 and S2, as well as a silicon oxide layer 123 on the surface of the substrate 100. This step may also partially remove the first spacer layer 112, which is likewise made of silicon oxide. Next, a photoresist layer 124 is formed over the outer regions of the stacked structures S1 and S2. In this embodiment, the photoresist 124 fully covers the outer region and partially covers the stacked structures S1 and S2, while leaving the inner region—specifically the portions of spacer 116 between the stacked structures—exposed, thereby creating an opening between the stacked structures S1 and S2. Using the photoresist 124 and the stacked structures S1 and S2 as masks, an ion implantation process is then carried out to form a doped region in the substrate 100, thereby creating a source region 126. Subsequently, an etching process—such as wet etching—is performed to remove the silicon oxide layer 123 and the oxide spacers 122 in the inner region, resulting in the structure depicted in the figure. As illustrated in this embodiment, the formed source region 126 is shared by both adjacent stacked structures S1 and S2 (i.e., by both memory cells), and may also be referred to as a source line.

Please refer to FIG. 7. After the formation of the source region S, the photoresist 124 in the outer region is removed. A high-temperature thermal annealing process is then carried out to activate the implanted ions, thereby completing the diffusion and final formation of the source region S. Subsequently, a conformal insulating layer 128 is formed over the entire structure, covering both the substrate 100 as well as the surfaces of the stacked structures S1 and S2. A photoresist layer 130 is then applied over the inner region between the stacked structures S1 and S2. In this embodiment, the photoresist 130 fully covers the inner region and partially covers the insulating layer 128, but does not cover the portions of the insulating layer 128 located in the outer region. Using the photoresist 130 as a mask, an anisotropic dry etching process followed by an isotropic wet etching process is performed to remove the insulating layer 128 in the outer region, as well as the silicon oxide layer 123 on the substrate 100. This step also reduces the thickness of the oxide spacers 122 on the outer sidewalls of the stacked structures S1 and S2, resulting in the structure shown in FIG. 7. The remaining portion of the insulating layer 128 in the inner region serves as the gate dielectric layer between the erase gate (to be formed in later steps) and the substrate. In some embodiments, a partial oxidation treatment may be applied to the source S of the substrate 100 to increase the thickness of the insulating layer 128 above the source S.

Please refer to FIG. 8. Following the formation of insulating layer 128, the photoresist 130 is removed, and another conformal insulating layer 132 is deposited over the entire structure. Preferably, the insulating layer 132 includes a first thin silicon oxide layer, which functions as an interface layer (IL), and a second high-k dielectric material layer (having a dielectric constant K greater than that of silicon oxide), made of high-k materials such as HfO₂, ZrO₂, TiO₂, Ta₂O₅, or other suitable materials. The thickness of insulating layer 132 can be adjusted to tune the threshold voltage of the select gate (i.e. word line) in split-gate flash memory cells. Moreover, the insulating layer 132 may include a capping layer, such as TiN, TaN, or TiSiN, to protect the high-k material from potential damage in subsequent processing steps.

Referring again to FIG. 8. After the formation of the insulating layer 132, the photoresist 130 is removed, and a polysilicon layer is deposited over the entire structure. A chemical mechanical polishing (CMP) process is then performed to remove portions of the structure above a certain height, resulting in the formation of a polysilicon layer 134a in the inner region and a polysilicon layer 134b in the outer region, as illustrated in FIG. 8. It can be seen that the top surfaces of the polysilicon layers 134a and 134b are flush with the top surface of the hard mask 110a of the stacked structures S1 and S2. In the present invention, the aforementioned polysilicon layer 134a serves as the material layer for forming the erase gate (EG) of the memory device, while the polysilicon layer 134b functions as the material layer for the word line (i.e., the select gate) of the memory cell. These polysilicon layers 134a and 134b may also be utilized as gate material layers in logic regions of the wafer, including both core and non-core logic areas.

Please refer to FIG. 9. Following the formation of the polysilicon layers 134a and 134b, an etching process is performed to partially remove both the polysilicon layers 134a and 134b, reducing their height to a level below the top surface of the hard mask layer 110. As a result, the polysilicon layer 134a located in the inner region between the stacked structures S1 and S2 is shaped into the erase gate (EG) of the memory cell. Meanwhile, the polysilicon layer 134b located in the outer region of the stacked structures S1 and S2 will be used to form the word lines in subsequent processing steps.

Please refer to FIG. 10. After the formation of the erase gate EG, a photoresist 136 is applied over the substrate 100. In this embodiment, the photoresist 136 covers the stacked structures S1 and S2 and defines the outer edge of the word lines to be formed in the regions outside the stacked structures S1 and S2. Notably, unlike conventional skills, the photoresist 136 in the present invention also includes two openings 136a, each positioned above the hard mask layers 110a of the stacked structures S1 and S2, respectively. These openings serve to define contact openings in the hard mask 110a. Once the photoresist 136 is formed, an anisotropic etching process is carried out to remove the exposed portions of the polysilicon layer 134b and the hard mask layer 110a. As a result, the polysilicon layer 134b located in the outer region of the stacked structures S1 and S2 becomes the word line (WL), and contact openings 110b are formed in the hard mask 110a, thereby exposing the underlying control gates CG.

In conventional approaches, such contact openings 110b in memory cells are typically formed through separate processing steps, each involving its own dedicated photomasks, photoresist, and photolithography processes. In contrast, the present invention integrates the formation of the contact openings 110b in the hard mask 110a with the same process used to define the word lines WL, using a shared photomask, photoresist, and lithography step. This streamlined integration reduces both the number of photomasks and photolithography steps required in the manufacture of the memory device, offering significant cost savings and marking a key advantage and innovation of the present invention.

Please refer to FIG. 11. Following the formation of the contact openings 110b and the word lines WL, a lightly doped (N−) ion implantation process I1 is performed using the photoresist 136 as an implantation mask, thereby forming lightly doped drains (LDD) 138 in the substrate 100. In this embodiment, the LDDs 138 are configured such that the junctions of the bit lines are exposed on both sides of the word lines WL, with part of the LDDs overlapping the word lines WL in the vertical direction. In the embodiment, additionally, a similar or different ion implantation process may be carried out in the logic region of the wafer to form LDD structures for logic devices.

Please refer to FIG. 12. Following the formation of the LDDs 138, the photoresist 136 is removed. Spacers 139 are then formed along the sidewalls of the word lines WL and the hard mask layer 110a. These spacers 139 are typically composed of silicon nitride, and can be formed by depositing a silicon nitride layer followed by an anisotropic etching process. It is worth noting that the spacers 139 may also form in the contact openings 110b of the hard mask 110a. However, this does not affect final dimensions of the contact holes to be formed in later steps. After forming the spacers 139, a heavily doped (N+) ion implantation process I2 is performed, using the spacers 139, word lines WL, stacked structures S1 and S2, and the erase gate EG as masks, followed by a thermal activation process. This results in the formation of drains D in the substrate 100, adjacent to the spacers 139 and electrically connected to the previously formed LDDs 138. In a similar manner, either identical or alternative ion implantation processes may be employed to form the sources and drains of logic devices within the logic region of the wafer.

Please refer to FIG. 13. After the formation of the drains D, an interlayer dielectric (ILD) 141 is deposited over the entire surface of the substrate 100. This ILD layer may be composed of silicon oxide or low-k dielectric material. The formed ILD layer 141 covers the aforementioned word lines WL, the stacked structures S1 and S2, the erase gate EG, and may also fill the contact openings 110b in the hard mask 110a. Subsequently, a photolithography process is employed to define and form contact holes 140 in the ILD layer 141, corresponding to the terminals of various components, such as the erase gate EG, control gate CG, word lines WL, and drains D. In this embodiment, the contact holes 140 may be smaller than, or in contact with the underlying contact openings 110b of the hard mask 110a, although the invention is not limited to this particular configuration. Finally, a metal layer is deposited into the contact holes 140, forming contacts 142 that electrically connect these terminals to external circuitry. These contacts enable electrical operations such as programming, erasing, and reading of the memory cells.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing a memory device, comprising:
providing a substrate;
sequentially forming a first insulating layer, a first silicon layer, a second insulating layer, a second silicon layer, and a mask layer over the substrate;
patterning the mask layer, the second silicon layer, and the second insulating layer into two stacked structures, wherein the mask layer, the second silicon layer, and the second insulating layer are respectively transformed into a hard mask, a control gate, and a blocking oxide layer within each of the two stacked structures;
patterning the first silicon layer and the first insulating layer into a floating gate and a tunnel oxide layer within each of the two stacked structures;
forming a source in the substrate between the two stacked structures;
forming a polysilicon layer between and outside the two stacked structures;
performing a photolithography process to pattern the two hard masks and the polysilicon layer, thereby forming a contact opening in each hard mask to expose the control gates, and transforming the polysilicon layer outside the two stacked structures into two word lines;
forming a drain on each outer side of the two word lines; and
forming contacts in the two contact openings to electrically connect to the two control gates.

2. The method of manufacturing a memory device of claim 1, further comprising performing an etching process before the photolithography process to reduce the height of the polysilicon layer below top surfaces of the two hard masks, such that the polysilicon layer between the two stacked structures is transformed into an erase gate.

3. The method of manufacturing a memory device of claim 2, further comprising:
forming a third insulating layer on sidewalls of the two stacked structures between the two stacked structures and over the substrate before forming the polysilicon layer, wherein the third insulating layer is located between the erase gate and the substrate.

4. The method of manufacturing a memory device of claim 2, further comprising:
performing a chemical mechanical polishing process before the etching process to remove portions of the polysilicon layer and the two hard masks above a certain height, such that a top surface of the polysilicon layer is flush with the top surfaces of the two hard masks.

5. The method of manufacturing a memory device of claim 1, wherein the step of forming the contacts comprises:
forming an interlayer dielectric layer over the substrate, covering the two word lines and the two stacked structures;
forming contact holes in the interlayer dielectric layer, each of the contact holes being located in the respective contact opening and exposing the corresponding control gate; and
filling metal into the contact holes to form the contacts.

6. The method of manufacturing a memory device of claim 1, further comprising forming first spacers on sidewalls of the stacked structures after forming the hard mask, the control gate, and the blocking oxide layer.

7. The method of manufacturing a memory device of claim 6, further comprising using the two hard masks and the first spacers as masks to etch the first silicon layer and the first insulating layer, thereby patterning the first silicon layer and the first insulating layer into the floating gate and the tunnel oxide layer in each of the two stacked structures.

8. The method of manufacturing a memory device of claim 1, further comprising forming a fourth insulating layer on sidewalls of the two stacked structures outside the two stacked structures and over the substrate before forming the polysilicon layer, wherein the fourth insulating layer is located between the two word lines and the substrate.

9. The method of manufacturing a memory device of claim 1, further comprising forming lightly doped drains on outer sides of the two word lines, wherein each of the LDDs is electrically connected to the corresponding drain.

10. The method of manufacturing a memory device of claim 1, further comprising forming second spacers on sidewalls of the two word lines, and performing an ion implantation process using the second spacers as a mask to form the drains on the outer sides of the two word lines.
